(19) United States
(12) Patent Application Publication
(10) Pub. No.: US 2009/0152530 A1
(43) Pub. Date: Jun. 18, 2009

(54) Image sensor including photoelectric charge-trap structure

(76) Inventors: Sung-Min Ahn, Ansan-si (KR); Jeong-Ho Lee, Seoul (KR)

Correspondence Address: LAW OFFICE OF MONICA H CHOI, P O BOX 3424, DUBLIN, OH, 430160204, US

(21) Appl. No.: 12/287,955

(22) Filed: Oct. 15, 2008

(30) Foreign Application Priority Data
Oct. 15, 2007 (KR) 10-2007-0103640

(51) Int. Cl. H01L 31/0352

(52) U.S. Cl. 257/24; 257/E31.033; 977/954

(57) ABSTRACT

A pixel of an image sensor includes a first insulating structure, a photoelectric charge-trap structure, a second insulating structure, and a gate electrode. The first insulating structure is formed on a substrate, and the photoelectric charge-trap structure is formed on the first insulating structure. The second insulating structure is formed on the photoelectric charge-trap structure. The gate electrode is formed on the second insulating structure. The photoelectric charge-trap structure converts a significant amount of light reaching the pixel into charge carriers.

This application claims priority under 35 USC § 119 to Korean Patent Application No. 10-2007-0103640, filed on Oct. 15, 2007 in the Korean Intellectual Property Office, the disclosure of which is incorporated herein in its entirety by reference.

### BACKGROUND OF THE INVENTION

1. Field of the Invention

The present invention relates generally to image sensors, and more particularly to an image sensor including a photoelectric charge-trap structure.

2. Background of the Invention

Image sensors are widely used in digital imaging applications because of their compact size, high image resolution, and low price. Image sensors are electronic devices having photoelectric transducers (or photoelectric generators) for converting light into electrical signals. Thus, the size of (i.e., area occupied by) each pixel or unit pixel in an image sensor is desired to be as small as possible to provide high quality and high resolution images.

However, conventional image sensors include photoelectric transducers such as photodiodes having a large area. Thus, reduction of the size of a unit pixel in the conventional image sensor is limited. Nevertheless, increasing the resolution of an image sensor is desired.

### SUMMARY OF THE INVENTION

Accordingly, a pixel of an image sensor according to an aspect of the present invention includes a first insulating structure, a photoelectric charge-trap structure, a second insulating structure, and a gate electrode. The first insulating structure is formed on a substrate, and the photoelectric charge-trap structure is formed on the first insulating structure. The second insulating structure is formed on the photoelectric charge-trap structure. The gate electrode is formed on the second insulating structure. The photoelectric charge-trap structure converts a significant amount of light reaching the pixel into charge carriers.

In an embodiment of the present invention, holes of the charge carriers in the photoelectric charge-trap structure tunnel through the first insulating structure to the substrate. In addition, electrons of such charge carriers are trapped in the photoelectric charge-trap structure. An amount of the electrons trapped in the photoelectric charge-trap structure indicates an intensity of light received by the photoelectric charge-trap structure. Furthermore, the electrons are trapped in the photoelectric charge-trap structure when the gate electrode is biased with a sampling voltage.

In a further embodiment of the present invention, the unit pixel includes a drain and a source formed to sides of the first insulating structure in the substrate. The electrons in the photoelectric charge-trap structure affect a level of current flowing through the drain and the source.

In another embodiment of the present invention, the electrons tunnel through the first insulating structure to the substrate when the gate electrode is biased with a reset voltage.

In a further embodiment of the present invention, the gate electrode and the second insulating structure are comprised of respective transparent materials.

In another embodiment of the present invention, the photoelectric charge-trap structure is comprised of at least one semiconductor material such as a hetero-junction semiconductor material including at least one of ZnₓO_{y}, AlₓGa_{y}N_{z}, AlₓN_{y}, GaₓAs_{y}, AlₓGa_{y}As_{z}, InₓAs_{y}, AlₓAs_{y}, and GaₓN_{y}.

In a further embodiment of the present invention, the photoelectric charge-trap structure is comprised of a semiconductor material having a lower conduction band energy level than the substrate.

In another embodiment of the present invention, the photoelectric charge-trap structure comprises a stack of multiple semiconductor materials having different conduction band energy levels. For example, the stack of the photoelectric charge-trap structure includes an intermediate semiconductor material having a lowest conduction band energy level of the multiple semiconductor materials.

Alternatively, the stack of the photoelectric charge-trap structure includes a first semiconductor material with a lower conduction band energy level and a higher thickness and a second semiconductor material with a higher conduction band energy level and a lower thickness.

In another example embodiment of the present invention, the stack of the photoelectric charge-trap structure includes a first semiconductor material with a higher photoelectric generation efficiency and a higher thickness and a second semiconductor material with a lower photoelectric generation efficiency and a lower thickness.

In a further example embodiment of the present invention, the photoelectric charge-trap structure includes multiple semiconductor materials with different conduction band energy levels arranged across a plane parallel to the substrate. In that case, the photoelectric charge-trap structure further includes a barrier layer disposed adjacent the plane. For example, the multiple semiconductor materials of the photoelectric charge-trap structure are arranged as a quantum wire structure. Alternatively, the multiple semiconductor materials of the photoelectric charge-trap structure are arranged as a cubic quantum well structure.

In another example embodiment of the present invention, the photoelectric charge-trap structure is a quantum dot structure.

In a method of operating a pixel in an image sensor according to another aspect of the present invention, a gate electrode of the pixel is biased with a sampling voltage for trapping charge carriers in a photoelectric charge-trap structure disposed under the gate electrode and over a first insulating structure formed on a substrate. The amount of the charge carriers, such as electrons, trapped in the photoelectric charge-trap structure indicates an intensity of light reaching the photoelectric charge-trap structure.

In addition, a drain of the pixel is biased for generating a drain current having a level that is determined by the amount of the charge carriers trapped in the photoelectric charge-trap structure. In that case, an image signal is determined for indicating the intensity of light received by the photoelectric charge-trap structure from the level of the drain current. Furthermore, the gate electrode is biased with a reset voltage for resetting the photoelectric charge-trap structure.

In this manner, the pixel of the image sensor is formed as compactly as a flash memory cell with the photoelectric charge-trap structure being part of a gate stack of the pixel. Thus, the area of each pixel is readily reduced for high image resolution of the image sensor. In addition, formation of quantum wells in the photoelectric charge-trap structure enhances quantum efficiency and charge retention rate of the photoelectric charge-trap structure.

### BRIEF DESCRIPTION OF THE DRAWINGS

The above and other features and advantages of the present invention will become more apparent when described in detailed exemplary embodiments thereof with reference to the attached drawings in which:

FIGS. 1, 2, 3, 4, 5, and 6 illustrate unit pixels each implemented with different gate stacks in image sensors, according to various embodiments of the present invention;

FIGS. 7A and 7B are energy band diagrams for explaining operations of the unit pixel of FIG. 1, according to an embodiment of the present invention;

FIGS. 8 and 9 are energy band diagrams for explaining operations of photoelectric charge-trap structures of the unit pixels of FIGS. 2 and 3, according to embodiments of the present invention;

FIG. 10 illustrates a method of forming a photoelectric charge-trap structure having a quantum dot structure according to an embodiment of the present invention; and

FIG. 11 shows a circuit diagram of a unit pixel of FIG. 1, 2, 3, 4, 5, or 6 for operation of such a unit pixel, according to an embodiment of the present invention.

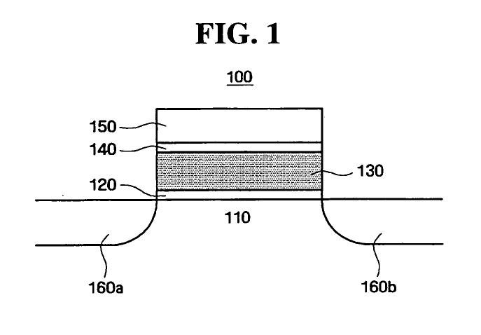

The figures referred to herein are drawn for clarity of illustration and are not necessarily drawn to scale. Elements having the same reference number in FIGS. 1, 2, 3, 4, 5, 6, 7A, 7B, 8, 9, 10, and 11 refer to elements having similar structure and/or function.

### DETAILED DESCRIPTION OF THE INVENTION

Embodiments of the present invention are understood more readily by reference to the following detailed description and the accompanying drawings. The present invention may, however, be embodied in many different forms and should not be construed as being limited to the embodiments set forth herein. Exemplary embodiments of the present invention are described herein with reference to cross-sectional views that are schematic illustrations of idealized embodiments of the present invention.

Thus, the shapes of structures described herein may vary from the illustrations as a result of manufacturing techniques and/or tolerances. Accordingly, the shapes of structures illustrated in the figures are schematic in nature and are not intended to illustrate the actual shapes or to limit the scope of the invention.

A term “photoelectric charge-trap structure” is used to refer to a region that acts both as a “photoelectric generator” that transforms received light into charge carriers and as a “charge-trap layer” that stores at least a portion of such charge carriers.

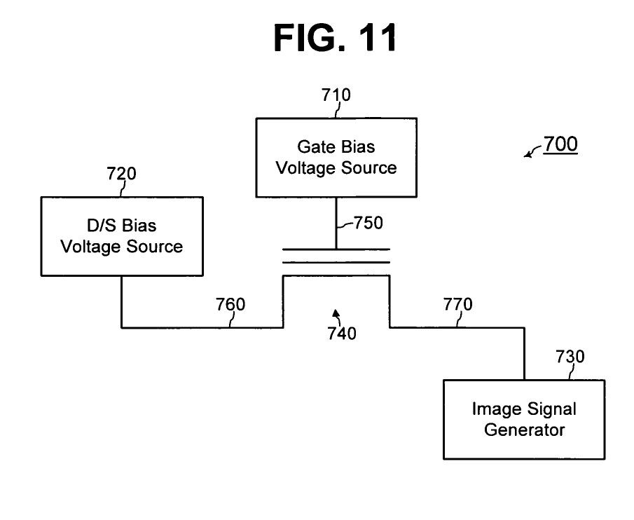

FIG. 11 shows an image sensor 700 according to an embodiment of the present invention. Such a image sensor 700 would include an array of unit pixels 740 having a gate stack structure formed as compactly as a flash memory cell. FIG. 11 shows an example unit pixel 740 with a drain electrode 760, a gate electrode 750, and a source electrode 770.

Further referring to FIG. 11, the image sensor 700 includes a drain bias voltage source generating a drain bias voltage applied on the drain electrode 760. The image sensor 700 also includes a gate bias voltage source 710 for generating a sampling voltage or a reset voltage applied on the gate electrode 750. An image signal generator 730 is coupled to the source electrode 770 for determining an image signal from a drain/source current flowing through the unit pixel 740.

FIGS. 1, 2, 3, 4, 5, and 6 show cross-sectional views for example embodiments of the unit pixel 740 in the image sensor of FIG. 11.

Referring to FIG. 1, a unit pixel 100 (which may be the unit pixel 740 of FIG. 11) includes a first insulating structure 120 that is a gate insulating structure formed over a channel region of a semiconductor substrate 110. The channel region is the portion of the semiconductor substrate 110 between a drain region 160a and a source region 160b.

Also in FIG. 1, the unit pixel 100 further includes a photoelectric charge-trap structure 130 formed on the gate insulating structure 120. Furthermore, a second insulating structure 140 that is a blocking structure is formed on the photoelectric charge-trap structure 130. Additionally, a gate electrode 150 is formed on the blocking structure 140.

In this manner, the unit pixel 100 includes a gate stack comprised of the gate insulating structure 120, the photoelectric charge-trap structure 130, the blocking structure 140, and the gate electrode 150 formed over the channel region of the substrate 110 disposed between the drain and source regions 160a and 160b. Such a structure of the unit pixel 100 is formed as compactly as a flash memory cell, but with a different functionality of a pixel in an image sensor.

The present invention may be implemented with the substrate 110 being one of various types of semiconductor substrates such as a silicon substrate, a silicon germanium substrate, a compound semiconductor substrate, a silicon on insulator (SOI) substrate, or a silicon on sapphire (SOS) substrate. In an example embodiment of the present embodiment, the substrate 110 is a silicon substrate. The present invention may also be practiced with a well region being formed within a semiconductor substrate. For example, the drain and source regions 160a and 160b are formed in a P-well within the substrate 110.

The gate insulating structure 120 is comprised of silicon oxide ((SiₓO_{y}) formed by thermally oxidizing the surface of the silicon substrate 110, in an example embodiment of the present invention. The gate insulating structure 120 is formed between the photoelectric charge-trap structure 130 and the substrate 110. The gate insulating structure 120 provides an energy barrier as holes generated within the charge-trap structure 130 tunnel to the substrate 110.

The photoelectric charge-trap structure 130 generates electron-hole pairs (EHPs) that are charge carriers upon absorbing light reaching the photoelectric charge-trap structure 130. Thus, the photoelectric charge-trap structure 130 serves as a photoelectric transducer of the image sensor. The photoelectric charge-trap structure 130 also retains at least a portion of the generated EHPs for storing information regarding the intensity of the received light.

According to an example embodiment of the present invention, the photoelectric charge-trap structure 130 is comprised of a semiconductor material such as a hetero-junction semiconductor material including at least one of zinc oxide (ZnₓO_{y}), aluminum gallium nitride (AlₓGa_{y}N_{z}), aluminum nitride (AlₓN_{y}), gallium arsenide (GaₓAs_{y}), aluminum gallium arsenide (AlₓGa_{y}As_{z}), indium arsenide (InₓAs_{y}), aluminum arsenide (AlₓAs_{y}), and gallium nitride (GaₓN_{y}). Hetero-junction semiconductor materials having various energy band gaps are amenable for forming the photoelectric charge-trap structure 130.

According to another embodiment of the present invention, the charge-trap structure 130 is comprised of a semiconductor material with a respective conduction band energy level that is lower than that of silicon (Si) for enhanced performance of the unit pixel 100. The charge-trap structure 130 with such a lower conduction band energy level results in higher retention of electrons therein.

Hetero-junction semiconductor materials containing aluminum (Al) tend to have a higher conduction band energy level than that of Si. Conversely, hetero-junction semiconductor materials containing gallium (Ga) tend to have a lower conduction band energy level than that of Si. Hetero-junction semiconductor materials containing indium (In) are likely to have a significantly lower conduction band energy level than that of Si. Thus, various hetero-junction semiconductor materials with different arrangements of such materials are used for desired functionality of the photoelectric charge-trap structure 130.

In addition, the composition of a hetero-junction semiconductor material affects the conduction band energy level of such a material. For example, if a GaAs hetero-junction semiconductor material has an energy band gap of 1.4 eV, a AlₓGa_{y}As_{z} hetero-junction semiconductor material including Al has a higher conduction band energy level that is increased according to the percentage of Al.

Conversely, a hetero-junction semiconductor material having indium (In) has a lower conduction band energy level that is decreased according to the percentage of In. Specifically, an AlₓGa_{y}N_{z} hetero-junction semiconductor material containing Al and Ga in the ratio of 3:7 (i.e., x:y=3:7) is known to have a conduction band energy level that is about 0.15 eV higher than the conduction band energy level of Si.

In contrast, GaN and ZnO semiconductor materials have conduction band energy levels that are about 0.65 eV and 0.85 eV, respectively, lower than the conduction band energy level of Si. The present invention may be practiced with various values of the conduction band energy level or the energy band gap of hetero-junction semiconductor materials.

The photoelectric charge-trap structure 130 may also be referred to as a “photoelectric generator” or “photoelectric transducer” for technically distinguishing the unit pixel 100 from other types of semiconductor devices such as flash memory cells. A charge-trap layer in a flash memory cell is an insulator, and does not and is not desired to generate charge carriers upon absorption of light.

In contrast, the photoelectric charge-trap structure 130 in the unit pixel 100 is desired to generate an amount of charge carriers significant enough for indicating the intensity of the received light. Thus, the photoelectric charge-trap structure 130 is comprised of a semiconductor material that generates such charge carriers upon absorption of light. Accordingly, the photoelectric charge-trap structure 130 in the unit pixel 100 of an image sensor has a completely different composition and function from the charge-trap layer in a flash memory cell that belongs to a different technical field of memory devices.

The blocking structure 140 prevents electrons and holes from tunneling there-through. Thus, the EHPs generated in the charge-trap structure 130 cannot leak into the gate electrode 150. In an example embodiment of the present invention, the blocking structure 140 is comprised of an insulating material such as hafnium oxide (HfₓO_{y}) or aluminum oxide ((AlO_{y}). Such HfₓO_{y} or AlₓO_{y} effectively prevents tunneling of electrons or holes, and is also formed simply and stably during general semiconductor processes. Furthermore, the blocking structure 140 may be comprised of an insulating material including lanthanum (La) which also effectively prevents tunneling of electrons and holes.

Referring to FIGS. 1 and 11, during operation of the image sensor 700, a positive (+) or negative (−) voltage is applied on the gate electrode 150 to polarize EHPs created in the photoelectric charge-trap structure 130 for affecting the channel region in the substrate 110. After the EHPs are generated within the photoelectric charge-trap structure 130, holes tunnel through the gate insulating structure 120 to the substrate 110, and the photoelectric charge-trap structure 130 retains the remaining electrons.

The channel region between the source and drain regions 160a and 160b in the substrate 110 is affected by a resulting electrical potential within the charge-trap structure 130. For example, the depth or width of such a channel region may be affected according to the amount of electrons retained by the charge-trap structure 130. In turn, the level of drain current flowing through the drain and source regions 160a and 160b (i.e., the drain and source electrodes 760 and 770 in FIG. 11) depends on the number of EHPs generated within the charge-trap structure 130. Accordingly, the level of current flowing through the drain and source regions 160a and 160b of the unit pixel 100 indicates the intensity of light absorbed by the photoelectric charge-trap structure 130 of the unit pixel 100.

In an example embodiment of the present invention, the gate electrode 150 and the blocking structure 140 are comprised of respective transparent materials. For example, the gate electrode 150 is comprised of a transparent and conductive material such as a ZnO semiconductor material. Such semiconductor material of the gate electrode 150 is doped with N-type ions for increased conductivity.

In an example embodiment of the present invention, the source and drain regions 160a and 160b are doped with N-type ions when the substrate 110 has P-type conductivity.

Operation of the image sensor 700 of FIG. 11 according to an example embodiment of the present invention is now described in more detail.

Referring to FIGS. 1 and 11, a sampling voltage that is typically a positive (+) voltage of several volts generated by the gate bias voltage source 710 is applied on the gate electrode 150 (i.e., 750 in FIG. 11). In addition, light is simultaneously received at the photoelectric charge-trap structure 130, and EHPs are generated therein from absorption of such light. With application of the positive sampling voltage on the gate electrode 150, electrons of the EHPs generated within the charge-trap structure 130 are attracted towards the blocking structure 140 while holes are tunneled away through the gate insulating structure 120 to the substrate 110.

The channel region of the unit pixel 100 becomes inverted adjacent the gate insulating structure 120 for electrically connecting the source and drain regions 160a and 160b with a drain current flowing from the drain region 160b to the source region 160a. The level of such drain current depends on the amount of EHPs generated within the photoelectric charge-trap structure 130.

That is, if the light absorbed by the photoelectric charge-trap structure 130 has higher intensity, a larger amount of EHPs are generated in the photoelectric charge-trap structure 130. Thus, a wider channel is formed so that a higher level of drain current flows between the source and drain regions 160a and 160b with a drain voltage generated by the drain bias voltage source 720 being applied on the drain electrode 760. Conversely, if the light absorbed by the photoelectric charge-trap structure 130 has lower intensity, a smaller level of drain current flows between the source and drain regions 160a and 160b.

The image signal generator 730 detects the level of such drain current flowing through the unit pixel 740 to generate an image signal indicating the intensity of light received at the photoelectric charge-trap structure 130 of the unit pixel 740. The image signal generator 730 may include other electronic devices for selection, transfer, and/or amplification. Depending on a color filter placed above the photoelectric charge-trap structure 130, such an image signal may be for one of red (R), green (G), and blue (B) pixels in the image sensor.

In an example embodiment of the present invention, the gate insulating structure 120 is formed thin enough such that holes (h+) of the EHPs generated in the photoelectric charge-trap structure 130 tunnel through the gate insulating structure 120 to the substrate 110 from application of the positive (+) sampling voltage on the gate electrode 150. In that case, the blocking structure 140 is formed thick enough such that the electrons of the EHPs generated in the photoelectric charge-trap structure 130 do not tunnel to the gate electrode 150. Thus, the photoelectric charge-trap structure 130 retains the remaining electrons that affect the level of drain current flowing through the source and drain regions 160a and 160b.

In this manner, the unit pixel 100 having the photoelectric charge-trap structure 130 as part of a gate stack instead of a photodiode is formed as compactly as a flash memory cell. An image sensor formed from an array of such unit pixels 100 may have higher resolution with more of such unit pixels fitting into a given area. In addition, for increasing efficiency of the photoelectric charge-trap structure 130, the gate electrode 150 is comprised of a substantially transparent and conductive material such as a ZnO or GaN semiconductor material that is known to be substantially transparent to light. Further physical/electronic characteristics of example material(s) of the photoelectric charge-trap structure 130 are described in more detail later herein.

Because the gate electrode 150 and the blocking structure 140 are comprised of substantially transparent materials, the photoelectric charge-trap structure 130 converts a significant amount of light reaching the unit pixel 700 into charge carriers. For example, the photoelectric charge-trap structure 130 absorbs and converts at least 80% of photon energy reaching the unit pixel 700 into charge carriers.

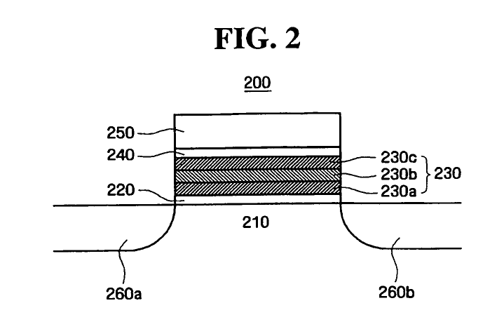

FIG. 2 shows a cross-sectional view of a unit pixel 200 (which may be the unit pixel 740 of FIG. 11) in an image sensor according to another embodiment of the present invention. Referring to FIG. 2, the unit pixel 200 includes a gate insulating structure 220, a photoelectric charge-trap structure 230 with a stack of three charge-trap layers 230a, 230b, and 230c, a blocking structure 240, and a gate electrode 250. Such structures form a gate stack over a channel region between source and drain regions 260a and 260b within a substrate 210. The structures 220, 240, 250, 260a, 260b, and 210 of FIG. 2 are similar in structure and function to the structures 120, 140, 150, 160a, 160b, and 110 of FIG. 1.

However in FIG. 2, the charge-trap layers 230a, 230b, and 230c have at least two different conduction band energy levels. For example, such charge-trap layers 230a, 230b, and 230c are comprised of different materials with different conduction band energy levels for forming a quantum well that trap charges, resulting in improved quantum efficiency and charge retention. For example, electrons are stably trapped in such a quantum well because more energy is needed to move to another region. Also, performance of the photoelectric charge-trap structure 230 may be further improved by adjusting the thicknesses of the charge-trap layers 230a, 230b, and 230c.

In an example embodiment of the present invention, the lowermost and uppermost charge-trap layers 230a and 230c are comprised of a same material and the intermediate charge-trap layer 230b is comprised of a different material. However, the present invention is not limited thereto, and the present invention may be practiced with the charge-trap layers 230a, 230b, and 230c being comprised of three different materials with three different energy band gaps.

In that case, the characteristics of the charge-trap structure 230 depend on the location of one of the charge-trap layers 230a, 230b, and 230c having the highest or lowest conduction band energy level. That is, if one of the charge-trap layers 230a, 230b, and 230c with the highest conduction band energy level is formed in the middle of the stack with the other charge-trap layers having lower conduction band energy levels, two quantum wells are formed. Conversely, if one of the charge-trap layers 230a, 230b, and 230c with the lowest conduction band energy level is formed in the middle of the stack, one quantum well is formed.

The characteristics of the charge-trap structure 230 also depend on the physical properties of the gate insulating structure 220 and the blocking structure 240. For example, when the gate insulating structure 220 is formed for easy tunneling of charge carriers there-through, if a charge-trap layer with the lowest conduction band energy level is formed adjacent the gate insulating structure 220, holes may tunnel easily through the gate insulating structure 220. However in that case, the retention rate of electrons in the charge-trap structure 230 may be degraded.

Accordingly, a charge-trap layer with the highest conduction band energy level is formed adjacent the gate insulating structure 220 for ensuring high retention rate of electrons in the charge-trap structure 230. However, the present invention is not limited thereto, and the present invention may be practiced with various structures and materials of the charge-trap structure 230 for desired characteristics.

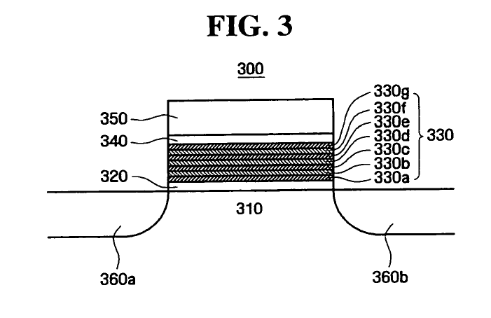

FIG. 3 shows a cross-sectional view of a unit pixel 300 (which may be the unit pixel 740 of FIG. 11) in an image sensor according to another embodiment of the present invention. Referring to FIG. 3, the unit pixel 300 includes a gate insulating structure 320, a photoelectric charge-trap structure 330 having a stack of multiple charge-trap layers 330a, 330b, 330c, 330d, 330e, 330f, and 330g, a blocking structure 340, and a gate electrode 350. Such structures form a gate stack over a channel region between source and drain regions 360a and 360b within a substrate 310. The structures 320, 340, 350, 360a, 360b, and 310 of FIG. 3 are similar in structure and function to the structures 120, 140, 150, 160a, 160b, and 110 of FIG. 1.

However in FIG. 3, the charge-trap layers 330a, 330b, 330c, 330d, 330e, 330f, and 330g have at least two different conduction band energy levels. In an example embodiment of the present invention, the charge-trap structure 330 is formed with the charge-trap layers 330a, 330b, 330c, 330d, 330e, 330f, and 330g alternating as two different conduction band energy levels as illustrated in FIG. 3, or with three or more different conduction band energy levels.

In this manner, the charge-trap structure 330 is formed with multiple quantum wells for increased quantum efficiency and retention rate of the charge-trap structure 330. Thus, photosensitivity and image quality of the image sensor may be enhanced. To further improve quantum efficiency, the thicknesses of the charge-trap layers 330a, 330b, 330c, 330d, 330e, 330f, and 330g may be adjusted.

For example, for improved retention rate of trapped electrons, a charge-trap layer with a lower conduction band energy level is formed to be thicker than a charge-trap layer with a higher conduction band energy level. Alternatively, a charge-trap layer that is capable of generating a larger number of EHPs for a given level of absorbed photon energy (i.e., with higher photoelectric-generation efficiency) is formed thicker than a charge-trap layer with lower photoelectric-generation efficiency.

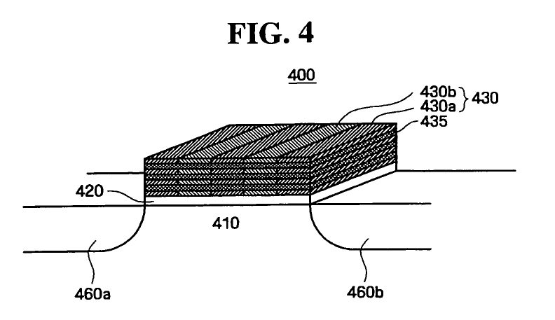

FIG. 4 shows a cross-sectional view of a unit pixel 400 (which may be the unit pixel 740 of FIG. 11) in an image sensor according to another embodiment of the present invention. Referring to FIG. 4, the unit pixel 400 includes a gate insulating structure 420, a photoelectric charge-trap structure 430 having multiple photoelectric charge-trap materials 430a and 430b and a barrier layer 435, a blocking structure (not shown in FIG. 4), and a gate electrode (not shown in FIG. 4). Such structures form a gate stack over a channel region between source and drain regions 460a and 460b within a substrate 410.

The unit pixel 400 of FIG. 4 differs from the unit pixel 100 of FIG. 1 in that the charge-trap structure 430 has a quantum wire structure whereby the multiple photoelectric charge-trap materials 430a and 430b are alternately arranged along a plane that is parallel to the surface of the substrate 410. The barrier layer 435 is disposed adjacent to such a plane of the photoelectric charge-trap materials 430a and 430b, and is disposed to alternate with the plane of the charge-trap materials 430a and 430b in a stack forming the photoelectric charge-trap structure 430.

The barrier layer 435 has a conduction band energy level that is higher than the lowest conduction band energy level of the photoelectric charge-trap materials 430a and 430b. The conduction band energy level of the barrier layer 435 is not necessarily higher than the highest conduction band energy level of the photoelectric charge-trap materials 430a and 430b. In an example embodiment of the present invention, the barrier layer 435 has a higher conduction band energy level than both of the photoelectric charge-trap materials 430a and 430b.

Alternatively, the barrier layer 435 has a conduction band energy level that is equal to a higher conduction band energy level of the photoelectric charge-trap materials 430a and 430b. In another embodiment of the present invention, the barrier layer 435 is comprised of a same material as one of the photoelectric charge-trap materials 430a and 430b with a higher conduction band energy level. In that case, the photoelectric charge-trap structure 430 is formed using two photoelectric charge-trap materials. In an embodiment of the present invention, the barrier layer 435 is comprised of a semiconductor material such as a hetero-junction semiconductor material.

The photoelectric charge-trap structure 330 of FIG. 3 includes multiple charge-trap materials varying along a vertical direction perpendicular to the surface of the substrate 310. In contrast, the photoelectric charge-trap structure 430 of FIG. 4 includes multiple charge-trap materials varying along both vertical and horizontal directions that are perpendicular and parallel to the surface of the substrate 310. Thus, the charge-trap layer 430 of FIG. 4 includes a larger number of quantum wells than the charge-trap layer 330 of FIG. 3 for improved quantum efficiency and charge retention rate.

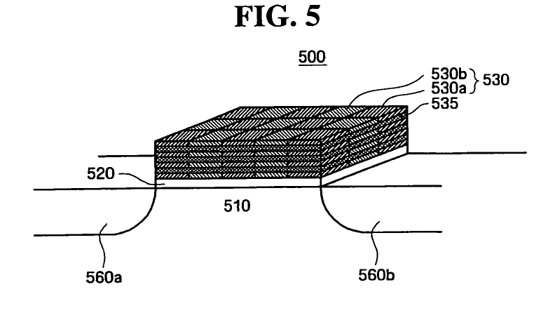

FIG. 5 shows a cross-sectional view of a unit pixel 500 (which may be the unit pixel 740 of FIG. 11) in an image sensor according to another embodiment of the present invention. Referring to FIG. 5, the unit pixel 500 includes a gate insulating structure 520, a photoelectric charge-trap structure 530 having multiple photoelectric charge-trap materials 530a and 530b and a barrier layer 535, a blocking structure (not shown in FIG. 5), and a gate electrode (not shown in FIG. 5). Such structures form a gate stack over a channel region between source and drain regions 560a and 560b within a substrate 510.

The unit pixel 500 of FIG. 5 differs from the unit pixel 100 of FIG. 1 in that the charge-trap structure 530 has a cubic shaped quantum well structure with the multiple photoelectric charge-trap materials 530a and 530b being alternately arranged in a checker-board pattern along a plane that is parallel to the surface of the substrate 510. In addition, the barrier layer 535 is disposed adjacent such a plane and is disposed to alternate with the plane of the charge-trap materials 530a and 530b in a stack forming the photoelectric charge-trap structure 530.

In an example embodiment of the present invention, the charge-trap materials 530a and 530b and the barrier layer 535 are comprised of two or more hetero-junction semiconductor materials with different conduction band energy levels. For example, the charge-trap materials 530a and 530b are comprised of two materials with different conduction band energy levels. In that case, the barrier layer 535 is comprised of the same material as one of the charge-trap materials 530a and 530b having a higher conduction band energy level. Alternatively, the charge-trap materials 530a and 530b and the barrier layer 535 are comprised of different materials.

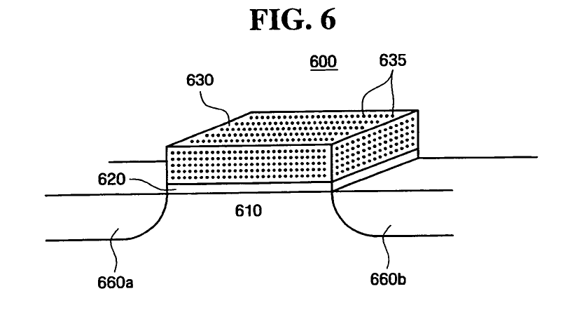

FIG. 6 shows a cross-sectional view of a unit pixel 600 (which may be the unit pixel 740 of FIG. 11) in an image sensor according to another embodiment of the present invention. Referring to FIG. 6, the unit pixel 600 includes a gate insulating structure 620, a photoelectric charge-trap structure 630 having a quantum dot structure, a blocking structure (not shown in FIG. 6), and a gate electrode (not shown in FIG. 6). Such structures form a gate stack over a channel region between source and drain regions 660a and 660b within a substrate 610.

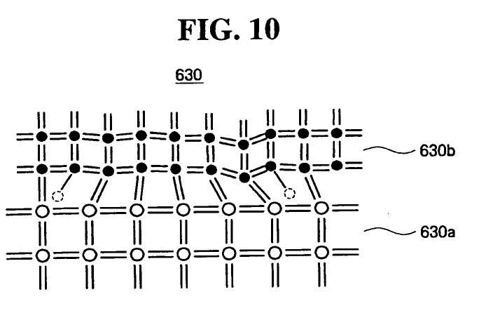

The photoelectric charge-trap structure 630 having the quantum dot structure includes a large number of quantum dots that are embedded therein for trapping charge carriers. Unlike the previous embodiments in which the charge-trap structures 230, 330, and 430 are comprised of multiple charge-trap layers with different conduction band energy levels, the charge-trap structure 630 of FIG. 6 includes a stack of materials with different lattice constants formed into the shape of quantum dots. A method of forming the charge-trap structure 630 having a stack of quantum dots will be described in more detail later in reference to FIG. 10.

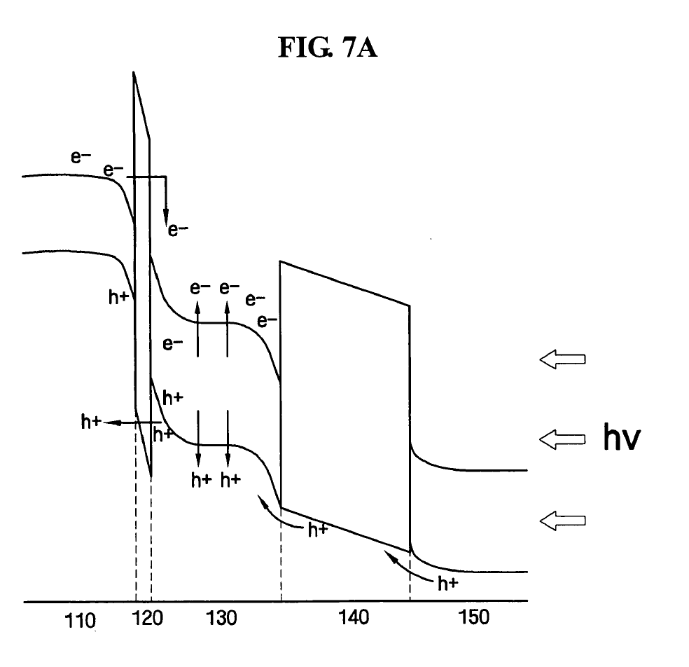

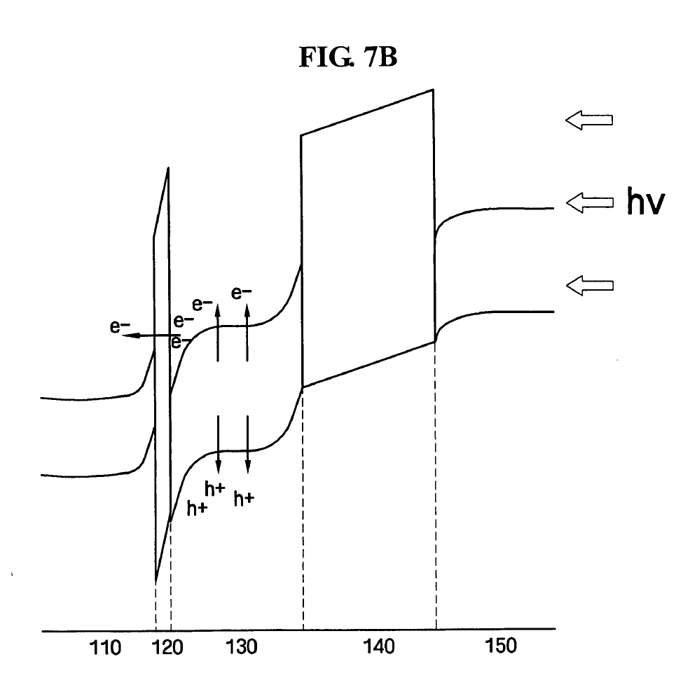

FIG. 7A shows an energy band diagram during transfer of electrons into a photoelectric charge-trap structure such as during capture of an image in the unit pixel 700 of FIG. 11, according to an embodiment of the present invention. FIG. 7B shows an energy band diagram during release of electrons from a photoelectric charge-trap structure such as during resetting of the unit pixel 700 of FIG. 11, according to an embodiment of the present invention.

Referring to FIG. 7A, upon absorption of photon energy hv within the photoelectric charge-trap structure 130, EHPs are generated within the photoelectric charge-trap structure 130. Upon application of a positive (+) sampling voltage on the gate electrode 150, electrons within the charge-trap structure 130 move towards the blocking layer 140 while holes tunnel through the gate insulating structure 120 to the substrate 110.

The blocking structure 140 acts as an energy barrier that is sufficiently thick to prevent the electrons from tunneling there-through. Thus, the electrons are attracted toward the blocking layer 140 to form an inversion region adjacent to the blocking layer 140. Conversely, the gate insulating structure 120 is much thinner than the blocking layer 140 such that the holes tunnel from the photoelectric charge-trap structure 130 through the gate insulating structure 120 to the substrate 110.

The amount of EHPs generated in the photoelectric charge-trap structure 130 and the amount of electrons retained in the photoelectric charge-trap structure 130 are dependent on the intensity of photon energy hv reaching the photoelectric charge-trap structure 130. The amount of electrons retained in the photoelectric charge-trap structure 130 also affects the channel region and thus the level of the drain current flowing between the source and drain regions (160a and 160b in FIG. 1).

Referring to FIG. 7B, upon application of a negative (−) reset voltage on the gate electrode 150, electrons within the photoelectric charge-trap structure 130 tunnel through the gate insulating structure 120 to the substrate 110 leaving a vacant state. Such a operation is for resetting the unit pixel of the image sensor.

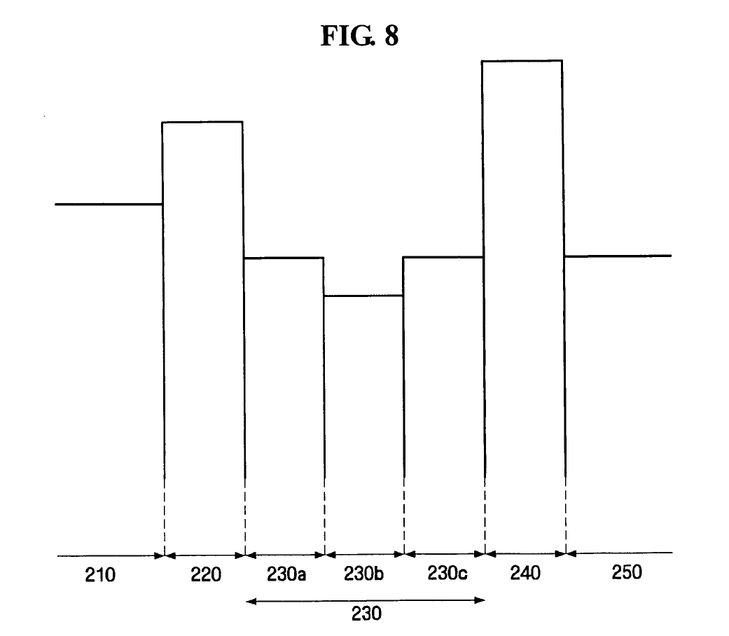

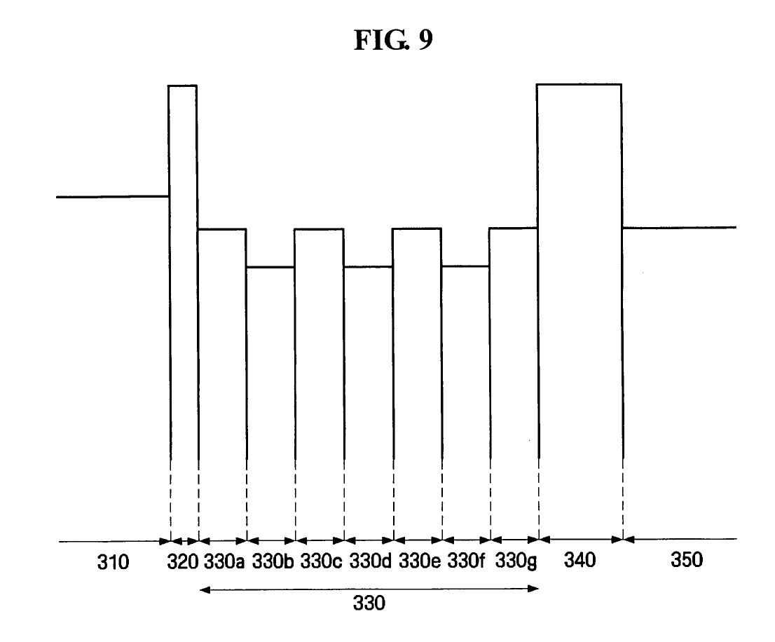

FIGS. 8 and 9 show energy band diagrams for the photoelectric charge-trap structures according to embodiments of the present invention. For example, FIG. 8 shows the energy band diagrams of the photoelectric charge-trap structure 230 of FIG. 2 having the three charge-trap layers 230a, 230b, and 230c. In FIG. 8, the intermediate charge-trap layer 230b has the lowest conduction band energy level such that electrons accumulate in such a low conduction band of the intermediate charge-trap layer 230b to form one quantum well.

The electrons accumulated in the lower conduction band of the intermediate charge-trap layer 230b need more energy to move to another conduction band of the lowermost and uppermost charge-trap layers 230a or 230c (located to the left and right of the intermediate charge-trap layer 230b in FIG. 8). Thus, the electrons are retained in the lower conduction band of the intermediate charge-trap layer 230b for a longer period of time than if the electrons were accumulated in a charge-trap structure with a single conduction band. Thus, the photoelectric charge-trap structure 230 with multiple conduction bands has improved charge retention.

FIG. 9 shows the energy band diagrams of the photoelectric charge-trap structure 330 of FIG. 3 having the seven charge-trap layers 330a, 330b, 330c, 330d, 330e, 330f, and 330g. The number of charge-trap layers formed for a photoelectric charge-trap structure may vary depending on the application.

In FIG. 9, the charge-trap layers 330b, 330d, and 330f have the lower conduction band energy levels than that of the other charge-trap layers 330a, 330c, 330e, and 330g. Thus, the charge-trap layers 330b, 330d, and 330f with the lower conduction band energy levels form three quantum wells within the photoelectric charge-trap structure 330. Such multiple multilevel quantum wells provide improved retention of trapped electrons for increased quantum efficiency.

FIG. 10 illustrates a method of forming the photoelectric charge-trap structure 630 of FIG. 6 having the quantum dot structure according to an embodiment of the present invention. Referring to FIG. 10, the photoelectric charge-trap structure 630 includes a first charge-trap layer 630a and a second charge-trap layer 630b formed on the first charge-trap layer 630a.

The first and second charge-trap layers 630a and 630b have different lattice constants. For example in FIG. 10, the first charge-trap layer 630a has a greater lattice constant than that of the second charge-trap layer 630b. When the second charge-trap layer 630b is formed on the first charge-trap layer 630a, some bonds between the first and second charge-trap layers 630a and 630b are broken due to a difference in lattice constant. Such broken bonds act as quantum dots. If another layer with a different lattice constant is formed on the second charge-trap layer 630b, other broken bonds would be generated. In this way, multiple quantum dots are formed by stacking materials with different lattice constants.

While the present invention has been particularly shown and described with reference to an exemplary embodiment thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. A pixel of an image sensor, the pixel comprising:
a first insulating structure formed on a substrate;
a photoelectric charge-trap structure formed on the first insulating structure;
a second insulating structure formed on the photoelectric charge-trap structure; and
a gate electrode formed on the second insulating structure,
wherein the photoelectric charge-trap structure converts a significant amount of light reaching the pixel into charge carriers.

2. The pixel of claim 1, wherein holes of said charge carriers tunnel through the first insulating structure to the substrate, and wherein electrons of said charge carriers are trapped in the photoelectric charge-trap structure.

3. The pixel of claim 2, wherein an amount of said electrons trapped in the photoelectric charge-trap structure indicates an intensity of light received by the photoelectric charge-trap structure.

4. The pixel of claim 2, further comprising:
a drain and a source formed to sides of the first insulating structure in the substrate, wherein the electrons in the photoelectric charge-trap structure affect a level of current flowing through the drain and the source.

5. The pixel of claim 4, further comprising:
an image signal generator for determining an image signal indicating the intensity of light absorbed by the photoelectric charge-trap structure from the level of the drain current.

6. The pixel of claim 2, wherein the electrons of said charge carriers are trapped in the photoelectric charge-trap structure when the gate electrode is biased with a sampling voltage.

7. The pixel of claim 6, wherein the electrons tunnel through said first insulating structure to the substrate when the gate electrode is biased with a reset voltage.

8. The pixel of claim 1, wherein the gate electrode and the second insulating structure are comprised of respective transparent materials.

9. The pixel of claim 1, wherein the photoelectric charge-trap structure is comprised of at least one semiconductor material.

10. The pixel of claim 9, wherein the photoelectric charge-trap structure is comprised of a hetero-junction semiconductor material including at least one of ZnₓO_{y}, AlₓGa_{y}N_{z}, AlₓN_{y}, GaₓAs_{y}, AlₓGa_{y}As_{z}, InₓAs_{y}, AlₓAs_{y}, and GaₓN_{y}.

11. The pixel of claim 1, wherein the photoelectric charge-trap structure is comprised of a semiconductor material having a lower conduction band energy level than the substrate.

12. The pixel of claim 1, wherein the photoelectric charge-trap structure comprises:
a stack of multiple semiconductor materials having different conduction band energy levels.

13. The pixel of claim 12, wherein the stack of the photoelectric charge-trap structure includes an intermediate semiconductor material having a lowest conduction band energy level of the multiple semiconductor materials.

14. The pixel of claim 12, wherein the stack of the photoelectric charge-trap structure includes a first semiconductor material with a lower conduction band energy level and a higher thickness and a second semiconductor material with a higher conduction band energy level and a lower thickness.

15. The pixel of claim 12, wherein the stack of the photoelectric charge-trap structure includes a first semiconductor material with a higher photoelectric generation efficiency and a higher thickness and a second semiconductor material with a lower photoelectric generation efficiency and a lower thickness.

16. The pixel of claim 12, wherein the photoelectric charge-trap structure includes multiple semiconductor materials with different conduction band energy levels arranged across a plane parallel to the substrate.

17. The pixel of claim 16, wherein the photoelectric charge-trap structure further includes a barrier layer disposed adjacent said plane.

18. The pixel of claim 16, wherein the multiple semiconductor materials of the photoelectric charge-trap structure are arranged as a quantum wire structure.

19. The pixel of claim 16, wherein the multiple semiconductor materials of the photoelectric charge-trap structure are arranged as a cubic quantum well structure.

20. The pixel of claim 1, wherein the photoelectric charge-trap structure is a quantum dot structure.
